(19) United States
(12) Patent Application Publication
(10) Pub. No.: US 2025/0323082 A1
(43) Pub. Date: Oct. 16, 2025

(54) SUBSTRATE PROCESSING APPARATUS, MEASURING DEVICE, AND MEASURING METHOD

(71) Applicant: Tokyo Electron Limited, Tokyo (JP)

(72) Inventor: Yuhei MATSUO, Koshi City (JP)

(73) Assignee: Tokyo Electron Limited, Tokyo (JP)

(21) Appl. No.: 19/175,014

(22) Filed: Apr. 10, 2025

(30) Foreign Application Priority Data
Apr. 12, 2024 (JP) 2024-064851

(51) Int. Cl. H01L 21/68; G01N 21/84; G01N 21/95

(52) U.S. Cl. CPC H01L 21/681; G01N 21/8422; G01N 21/9503; G01N 2021/8411; G01N 2021/8427

(57) ABSTRACT

A substrate processing apparatus includes a holder for holding a substrate allowed to be separated; an optical sensor, provided in the holder, for radiating measurement light to the substrate and receive reflection light from the substrate; a transparent member placed in a measurement light path between the substrate and the optical sensor, and allowed to transmit light; and a controller for processing measurement information from the optical sensor and for acquiring a distance between the substrate and the transparent member based on the measurement information to recognize a position of the substrate.

### CROSS-REFERENCE TO RELATED APPLICATION

This application claims the benefit of Japanese Patent Application No. 2024-064851 filed on Apr. 12, 2024, the entire disclosures of which are incorporated herein by reference.

### TECHNICAL FIELD

The various aspects and embodiments described herein pertain generally to a substrate processing apparatus, a measuring device, and a measuring method.

### BACKGROUND

Patent Document 1 discloses a bonding apparatus that has an upper chuck configured to attract a substrate at an upper side from above and a lower chuck configured to attract a substrate at a lower side from below, and bonds the two substrates face to face. In the bonding of the substrates, the bonding apparatus presses a central portion of the substrate attracted to the upper chuck into contact with a central portion of the substrate attracted to the lower chuck, and bonds the central portions of the two substrates together by a molecular force, allowing this bonding region to expand from the central portions to peripheral portions of the substrates.

In addition, in the bonding apparatus described in Patent Document 1, the upper chuck is equipped with multiple sensors configured to detect a progress (bonding wave) of the bonding between the substrates. For example, the multiple sensors are arranged at an equal distance along a circumferential direction of an outer periphery of the upper chuck, and serve to measure a height position of the substrate at the upper side, enabling recognition of the progress of the bonding.
Patent Document 1: Japanese Patent No. 6,929,427

### SUMMARY

In an exemplary embodiment, a substrate processing apparatus includes a holder configured to hold a substrate allowed to be separated; an optical sensor provided in the holder, and configured to radiate measurement light to the substrate and receive reflection light from the substrate; a transparent member placed in a measurement light path between the substrate and the optical sensor, and allowed to transmit light; and a processor configured to process measurement information from the optical sensor. The processor acquires a distance between the substrate and the transparent member based on the measurement information to recognize a position of the substrate.

### BRIEF DESCRIPTION OF THE DRAWINGS

FIG. 1 is a plan view illustrating a bonding apparatus;

FIG. 2 is a side view of the bonding apparatus of FIG. 1;

FIG. 3 is a side view illustrating an example of a first substrate and a second substrate;

FIG. 4 is a flowchart showing a bonding method;

FIG. 5 is a plan view illustrating an example of a bonding module according to a first exemplary embodiment;

FIG. 6 is a side view of the bonding module of FIG. 5;

FIG. 7 is a cross sectional view illustrating an example of an upper chuck and a lower chuck;

FIG. 8 is a flowchart showing details of a process S109 of FIG. 4;

FIG. 9A is a side view illustrating an example of an operation in a process S112 of FIG. 8, FIG. 9B is a side view illustrating an operation following that of FIG. 9A, and FIG. 9C is a side view illustrating an operation following that of FIG. 9B;

FIG. 10A is a cross sectional view illustrating an example of an operation in a process S113 of FIG. 8, FIG. 10B is a cross sectional view illustrating an example of an operation in a process S114 of FIG. 8, and FIG. 10C is a cross sectional view illustrating an operation following that of FIG. 10B;

FIG. 11 is a cross sectional view illustrating the upper chuck equipped with a displacement sensor;

FIG. 12 is an enlarged cross sectional view illustrating an outer displacement sensor and a gas discharger;

FIG. 13 is a diagram for explaining calculation of a distance between a transparent member and an upper wafer;

FIG. 14A is a diagram showing a measurement state of a displacement sensor according to a reference example, FIG. 14B is a diagram showing a measurement state in which a void reducing gas is introduced into a measurement light path of the displacement sensor according to the reference example, FIG. 14C is a diagram showing a measurement state of a displacement sensor according to the exemplary embodiment, and FIG. 14D is a diagram showing a measurement state in which the void reducing gas is introduced into the measurement light path of the displacement sensor according to the exemplary embodiment; and

FIG. 15 is a flowchart showing a bonding process of the upper wafer and a lower wafer, including a measuring method.

### DETAILED DESCRIPTION

Hereinafter, exemplary embodiments of the present disclosure will be described with reference to the accompanying drawings. In the various drawings, same or corresponding parts will be assigned same reference numerals, and redundant descriptions thereof will be omitted. Further, in the following description, the X-axis, Y-axis and Z-axis directions are perpendicular to each other. The X-axis direction and the Y-axis direction are horizontal directions, and the Z-axis direction is a vertical direction.

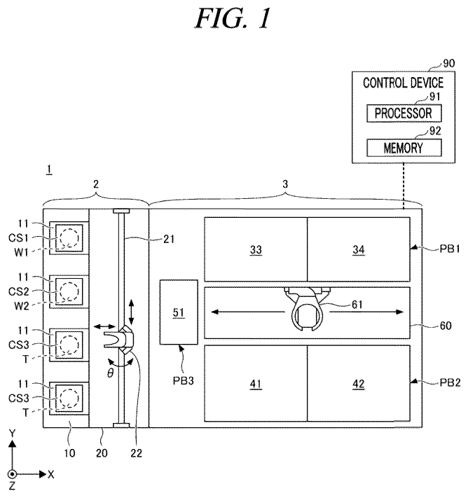

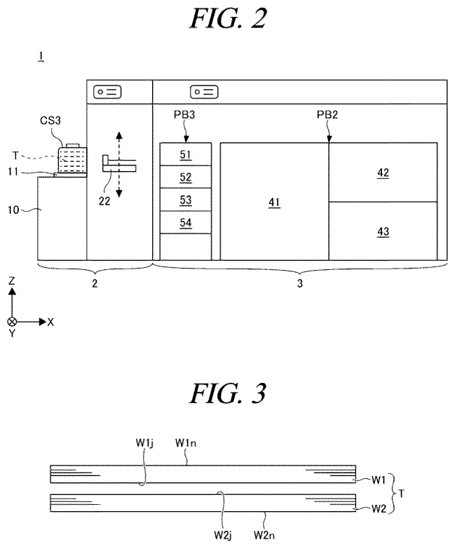

As a substrate processing apparatus of the present disclosure, a bonding apparatus 1 shown in FIG. 1 and FIG. 2 will be representatively described. The bonding apparatus 1 bonds a first substrate W1 and a second substrate W2 to produce a bonded substrate T. At least one of the first substrate W1 and the second substrate W2 is a semiconductor substrate such as, but not limited to, a silicon wafer or a compound semiconductor wafer on which a plurality of electronic circuits are formed. One of the first substrate W1 and the second substrate W2 may be a bare wafer on which no electronic circuit is formed. Though the compound semiconductor wafer is not particularly limited, it may be, by way of example, a GaAs wafer, a SiC wafer, a GaN wafer, or an InP wafer.

The first substrate W1 and the second substrate W2 are formed as circular plates having approximately the same shape (same diameter). As illustrated in FIG. 3, the bonding apparatus 1 bonds the first substrate W1 and the second substrate W2 after placing the second substrate W2 on the negative Z-axis side of (vertically under) the first substrate W1. Therefore, hereinafter, the first substrate W1 may sometimes be referred to as “upper wafer W1,” the second substrate W2 may sometimes be referred to as “lower wafer W2,” and the bonded substrate T may sometimes be referred to as the “bonded wafer T.” In addition, hereinafter, among plate surfaces of the upper wafer W1, the plate surface to be bonded to the lower wafer W2 will be referred to as “bonding surface W1j,” and the plate surface opposite to the bonding surface W1j will be referred to as “non-bonding surface W1n.” Likewise, among plate surfaces of the lower wafer W2, the plate surface to be bonded to the upper wafer W1 will be referred to as “bonding surface W2j”, and the plate surface opposite to the bonding surface W2j will be referred to as “non-bonding surface W2n”.

As shown in FIG. 1, the bonding apparatus 1 includes a carry-in/out station 2 and a processing station 3 arranged in this order in the positive X-axis direction. The carry-in/out station 2 and the processing station 3 are connected as one body.

The carry-in/out station 2 includes a placement table 10 and a transfer section 20. The placement table 10 is equipped with a multiple number of placement plates 11. Respectively provided on the placement plates 11 are cassettes CS1, CS2, and CS3 each of which accommodates therein a plurality of (e.g., 25 sheets of) substrates horizontally. The cassette CS1 accommodates therein upper wafers W1; the cassette CS2, lower wafers W2; and the cassette CS3, bonded wafers T. In the cassettes CS1 and CS2, the upper wafers W1 and the lower wafers W2 are accommodated in the same direction with their bonding surfaces W1j and Wj2 facing upwards, respectively.

The transfer section 20 is provided adjacent to the positive X-axis side of the placement table 10, and is equipped with a transfer path 21 extending in the Y-axis direction and a transfer device 22 configured to be movable along the transfer path 21. The transfer device 22 is configured to be movable in the X-axis direction as well as in the Y-axis direction and pivotable around the Z-axis, and serves to transfer the upper wafers W1, the lower wafers W2, and the bonded wafers T between the cassettes CS1 to CS3 placed on the placement table 10 and a third processing block PB3 of the processing station 3 to be described later.

The processing station 3 is provided with, for example, three processing blocks PB1, PB2, and PB3. The first processing block PB1 is disposed on the rear side of the processing station 3 (positive Y-axis side of FIG. 1). Further, the second processing block PB2 is provided on the front side of the processing station 3 (negative Y-axis side of FIG. 1), and the third processing block PB3 is disposed on the carry-in/out station 2 side of the processing station 3 (negative X-axis side of FIG. 1).

Further, the processing station 3 is equipped with a transfer section 60 having a transfer device 61 in a region surrounded by the first to third processing blocks PB1 to PB3. For example, the transfer device 61 has a transfer arm configured to be movable in a vertical direction and a horizontal direction and pivotable around a vertical axis. This transfer device 61 is moved within the transfer section 60 and transfers the upper wafers W1, the lower wafers W2 and the bonded wafers T to apparatuses within the first to third processing blocks PB1 to PB3 which are adjacent to the transfer section 60.

The first processing block PB1 has, by way of example, a surface modifying apparatus 33 and a surface hydrophilizing apparatus 34. The surface modifying apparatus 33 is configured to modify the bonding surface W1j of the upper wafer W1 and the bonding surface W2j of the lower wafer W2. The surface hydrophilizing apparatus 34 is configured to hydrophilize the modified bonding surfaces W1j and W2j of the upper and lower wafers W1 and W2.

For example, the surface modifying apparatus 33 cuts a SiO2 bond on the bonding surfaces W1j and W2j to form a dangling bond of Si, thus allowing the bonding surfaces W1j and W2j to be hydrophilized afterwards. In the surface modifying apparatus 33, an oxygen gas as a processing gas is excited into plasma to be ionized under a decompressed atmosphere, for example. As oxygen ions are radiated to the bonding surface W1j of the upper wafer W1 and the bonding surface W2j of the lower wafer W2, the bonding surfaces W1j and W2j are plasma-processed to be modified. The processing gas is not limited to the oxygen gas, but it may be a nitrogen gas or the like.

The surface hydrophilizing apparatus 34 is configured to hydrophilize the bonding surface W1j of the upper wafer W1 and the bonding surface W2j of the lower wafer W2 with a hydrophilizing liquid such as pure water. The surface hydrophilizing apparatus 34 also has a function of cleaning the bonding surfaces W1j and W2j. In the surface hydrophilizing apparatus 34, while rotating the upper wafer W1 or the lower wafer W2 held by, for example, a spin chuck, the pure water is supplied onto the upper wafer W1 or the lower wafer W2. Accordingly, the pure water is diffused on the bonding surfaces W1j and W2j, and an OH group is attached to the dangling bond of Si, so that the bonding surfaces W1j and W2j are hydrophilized.

As shown in FIG. 2, the second processing block PB2 includes, for example, a bonding module 41, a first temperature adjusting device 42, and a second temperature adjusting device 43. The bonding module 41 is configured to bond the hydrophilized upper wafer W1 and lower wafer W2 to produce the bonded wafer T. The first temperature adjusting device 42 is configured to adjust a temperature distribution of the upper wafer W1 before producing the bonded wafer T. The second temperature adjusting device 43 is configured to adjust a temperature distribution of the lower wafer W2 before producing the bonded wafer T. In addition, in the present exemplary embodiment, although the first temperature adjusting device 42 and the second temperature adjusting device 43 are provided separately from the bonding module 41, they may be provided as a part of the bonding module 41.

The third processing block PB3 is equipped with a first position adjusting device 51, a second position adjusting device 52, and transition devices 53 and 54 in this order from top to bottom, for example. Further, the places where the individual devices are disposed in the third processing block PB3 are not limited to the example shown in FIG. 2. The first position adjusting device 51 is configured to adjust the direction of the upper wafer W1 in a horizontal direction, and invert the upper wafer W1 upside down so that the bonding surface W1j of the upper wafer W1 faces downwards. The second position adjusting device 52 is configured to adjust the direction of the lower wafer W2 in the horizontal direction. The transition device 53 is configured to temporarily place therein the upper wafer W1. Further, the transition device 54 is configured to temporarily place therein the lower wafer W2 and the bonded wafer T.

Referring back to FIG. 1, the bonding apparatus 1 is equipped with a control device (controller) 90 configured to control the individual components. The control device 90 is a control computer having one or more processors 91, a memory 92, a non-illustrated input/output interface, and an electronic circuit. The one or more processors 91 are implemented by a combination of one or more of a CPU (Central Processing Unit), a GPU (Graphics Processing Unit), an ASIC (Application Specific Integrated Circuit), an FPGA (Field-Programmable Gate Array), a circuit composed of a plurality of discrete semiconductors, and the like. The memory 92 includes a nonvolatile memory and a volatile memory, and constitutes a storage of the control device 90. In other words, in the present disclosure, the control device 90 is an electronic circuit having CPU, GPU, ASIC, FPGA, or the like, and performs various control operations described in the present specification by executing instruction codes stored in the memory 92 or by being designed as a circuit for a specific purpose. The functionality of the elements disclosed herein may be implemented using circuitry or processing circuitry which includes general purpose processors, special purpose processors, integrated circuits, ASICS (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

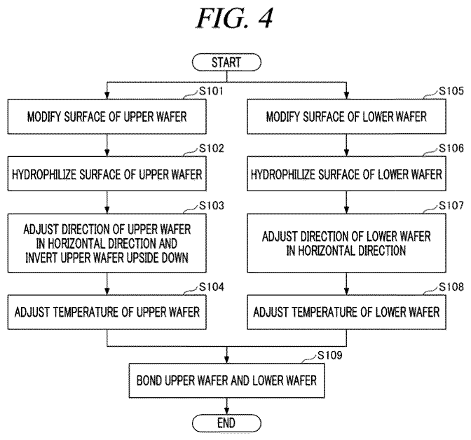

Now, referring to FIG. 4, a bonding method according to the present exemplary embodiment will be described. Processes S101 to S109 shown in FIG. 4 are performed under the control of the control device 90.

In the bonding method, a worker or a transfer robot (not shown) places the cassette CS1 accommodating the plurality of upper wafers W1, the cassette CS2 accommodating the plurality of lower wafers W2, and the empty cassette CS3 on the placement table 10 of the carry-in/out station 2.

The bonding apparatus 1 takes out the upper wafer W1 within the cassette CS1 by the transfer device 22, and transfers it to the transition device 53 of the third processing block PB3 of the processing station 3. Thereafter, the bonding apparatus 1 takes out the upper wafer W1 from the transition device 53 by the transfer device 61, and transfers it to the surface modifying apparatus 33 of the first processing block PB1.

Then, the bonding apparatus 1 modifies the bonding surface W1j of the upper wafer W1 by the surface modifying apparatus 33 (process S101). The surface modifying apparatus 33 modifies the bonding surface W1j while allowing the bonding surface W1j to face upwards. Thereafter, the transfer device 61 takes out the upper wafer W1 from the surface modifying apparatus 33, and transfers it to the surface hydrophilizing apparatus 34.

Then, the bonding apparatus 1 hydrophilizes the bonding surface W1j of the upper wafer W1 by the surface hydrophilizing apparatus 34 (process S102). The surface hydrophilizing apparatus 34 hydrophilizes the bonding surface W1j while allowing the bonding surface W1j to face upwards. Thereafter, the transfer device 61 takes out the upper wafer W1 from the surface hydrophilizing apparatus 34, and transfers it to the first position adjusting device 51 of the third processing block BP3.

The bonding apparatus 1 adjusts the direction of the upper wafer W1 in the horizontal direction by the first position adjusting device 51, and also turns the upper wafer W1 up and down (process S103). As a result, a notch of the upper wafer W1 is directed toward a predetermined direction, and the bonding surface W1j of the upper wafer W1 is turned downwards. Thereafter, the transfer device 61 takes out the upper wafer W1 from the first position adjusting device 51, and transfers it to the first temperature adjusting device 42 of the second processing block BP2.

The bonding apparatus 1 controls the temperature of the upper wafer W1 by the first temperature adjusting device 42 (process S104). The temperature adjustment of the upper wafer W1 is performed with its bonding surface W1j facing downwards. Thereafter, the transfer device 61 takes out the upper wafer W1 from the first temperature adjusting device 42, and transfers it to the bonding module 41.

The bonding apparatus 1 performs a processing on the lower wafer W2 in parallel with the above-described processing on the upper wafer W1. First, the bonding apparatus 1 takes out the lower wafer W2 within the cassette CS2 by the transfer device 22, and transfers it to the transition device 54 of the third processing block BP3 of the processing station 3. Thereafter, the transfer device 61 takes out the lower wafer W2 from the transition device 54, and transfers it to the surface modifying apparatus 33 of the first processing block BP1.

The bonding apparatus 1 modifies the bonding surface W2j of the lower wafer W2 by the surface modifying apparatus 33 (process S105). The surface modifying apparatus 33 modifies the bonding surface W2j while allowing the bonding surface W2j to face upwards. Thereafter, the transfer device 61 takes out the lower wafer W2 from the surface modifying apparatus 33, and transfers it to the surface hydrophilizing apparatus 34.

The bonding apparatus 1 hydrophilizes the bonding surface W2j of the lower wafer W2 by the surface hydrophilizing apparatus 34 (process S106). The surface hydrophilizing apparatus 34 hydrophilizes the bonding surface W2j while allowing the bonding surface W2j to face upwards. Thereafter, the transfer device 61 takes out the lower wafer W2 from the surface hydrophilizing apparatus 34, and transfers it to the second position adjusting device 52 of the third processing block BP3.

The bonding apparatus 1 adjusts the direction of the lower wafer W2 in the horizontal direction by the second position adjusting device 52 (process S107). As a result, a notch of the lower wafer W2 is directed toward a preset direction. Thereafter, the transfer device 61 takes out the lower wafer W2 from the second position adjusting device 52, and transfers it to the second temperature adjusting device 43 of the second processing block BP2.

The bonding apparatus 1 adjusts the temperature of the lower wafer W2 by the second temperature adjusting device 43 (process S108). The temperature adjustment of the lower wafer W2 is performed with its bonding surface W2j facing upwards. Thereafter, the transfer device 61 takes out the lower wafer W2 from the second temperature adjusting device 43, and transfers it to the bonding module 41.

Then, the bonding apparatus 1 bonds the upper wafer W1 and the lower wafer W2 in the bonding module 41 to produce the bonded wafer T (process S109). After the production of the bonded wafer T, the transfer device 61 takes out the bonded wafer T from the bonding module 41, and transfers it to the transition device 54 of the third processing block BP3.

Finally, the bonding apparatus 1 takes out the bonded wafer T from the transition device 54 by the transfer device 22, and transfers it to the cassette CS3 on the placement table 10. In this way, the series of processes are completed.

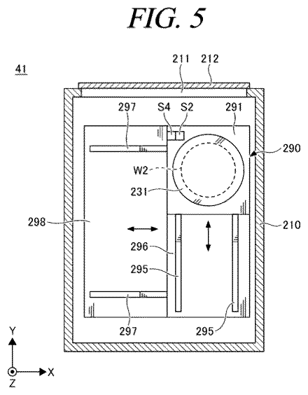

Now, referring to FIG. 5 to FIG. 7, an example of the bonding module 41 according to an exemplary embodiment will be described. As illustrated in FIG. 5, the bonding module 41 has a processing vessel 210 whose inside is hermetically sealable. A carry-in/out opening 211 is formed in a side surface of the processing vessel 210 on the transfer section 60 side, and an opening/closing shutter 212 is provided at the carry-in/out opening 211. The upper wafer W1, the lower wafer W2, and the bonded wafer T are carried in or out through the carry-in/out opening 211.

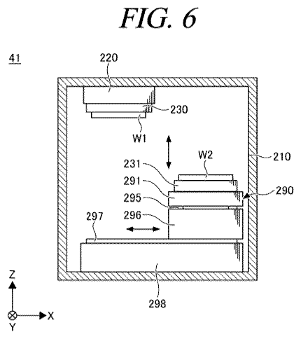

As depicted in FIG. 6, an upper chuck 230 and a lower chuck 231 are provided in the processing vessel 210. The upper chuck 230 is a first holder configured to hold the upper wafer W1 from above in a separable (displaceable) manner, allowing the bonding surface W1j of the upper wafer W1 to face downwards. The lower chuck 231 is a second holder that is provided below the upper chuck 230 and configured to hold the lower wafer W2 from below, allowing the bonding surface W2j of the lower wafer W2 to face upwards. In other words, the upper chuck 230 and the lower chuck 231 are holders that hold the upper wafer W1 and the lower wafer W2, which are substrates, in a separable manner, respectively.

The upper chuck 230 is supported by a supporting member 220 provided on a ceiling surface of the processing vessel 210. Meanwhile, the lower chuck 231 is supported by a first lower chuck mover 291 provided below the lower chuck 231.

The first lower chuck mover 291 moves the lower chuck 231 in a horizontal direction (Y-axis direction) as will be described later. In addition, the first lower chuck mover 291 is configured to be capable of moving the lower chuck 231 in a vertical direction and rotating it around a vertical axis.

The first lower chuck mover 291 is mounted to a pair of rails 295 provided on a bottom surface side of the first lower chuck mover 291 and extending in the horizontal direction (Y-axis direction). The first lower chuck mover 291 is configured to be movable along the rails 295. The rails 295 are provided on a second lower chuck mover 296.

The second lower chuck mover 296 is mounted to a pair of rails 297 provided on a bottom surface side of the second lower chuck mover 296 and extending in a horizontal direction (X-axis direction). The second lower chuck mover 296 is configured to be movable along the rails 297. In addition, the pair of rails 297 are disposed on a placement member 298 which is provided on a bottom surface of the processing vessel 210.

The first lower chuck mover 291 and the second lower chuck mover 296 constitute a moving mechanism 290. The moving mechanism 290 moves the lower chuck 231 relative to the upper chuck 230. Further, the moving mechanism 290 moves the lower chuck 231 between a substrate delivery position and a bonding position.

The substrate delivery position is a position where the upper chuck 230 receives the upper wafer W1 from the transfer device 61, the lower chuck 231 receives the lower wafer W2 from the transfer device 61, and the lower chuck 231 delivers the bonded wafer T to the transfer device 61. The substrate delivery position is a position where a carry-out of the bonded wafer T produced by the n^{th} (n is a natural number equal to or larger than 1) bonding and a carry-in of the upper wafer W1 and the lower wafer W2 to be bonded by the (n+1)^{th} bonding are performed in succession. The substrate delivery position is, for example, a position shown in FIG. 5 and FIG. 6.

When handing the upper wafer W1 over to the upper chuck 230, the transfer device 61 advances to a space directly under the upper chuck 230. Also, when receiving the bonded wafer T from the lower chuck 231 and handing the lower wafer W2 over to the lower chuck 231, the transfer device 61 advances to a space directly over the lower chuck 231. The upper chuck 230 and the lower chuck 231 are placed sideways apart and a distance between the upper chuck 230 and the lower chuck 231 in a vertical direction is large so that the transfer device 61 advances therebetween easily.

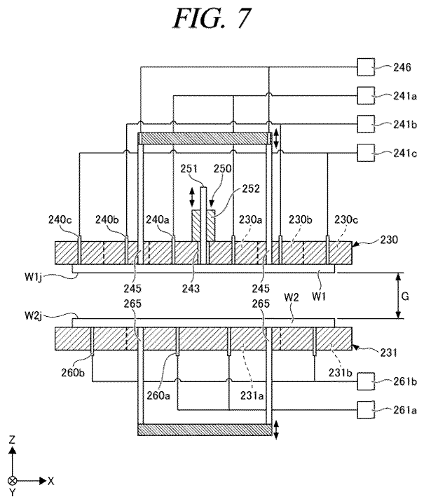

Meanwhile, the bonding position is a position where the upper wafer W1 and the lower wafer W2 are made to face each other with a preset distance therebetween. The bonding position is, for example, a position shown in FIG. 7. At the bonding position, the distance between the upper wafer W1 and the lower wafer W2 in the vertical direction is narrower than that at the substrate delivery position. Further, at the bonding position, the upper wafer W1 and the lower wafer W2 overlap each other when viewed from the vertical direction, unlike at the substrate delivery position.

The moving mechanism 290 moves the relative positions of the upper chuck 230 and the lower chuck 231 in the horizontal directions (both the X-axis direction and the Y-axis direction) and the vertical direction. Although the moving mechanism 290 moves the lower chuck 231 in the present exemplary embodiment, it may move any one of the lower chuck 231 and the upper chuck 230, or both of them. Further, the moving mechanism 290 may rotate the upper chuck 230 or the lower chuck 231 around a vertical axis.

As illustrated in FIG. 7, the upper chuck 230 is divided into a plurality of (for example, three) regions 230a, 230b, and 230c along a diametrical direction of the upper chuck 230. These regions 230a, 230b, and 230c are provided in this order from the center of the upper chuck 230 toward an outer periphery thereof. The region 230a is formed in a circular shape when viewed from the top, and the regions 230b and 230c are formed in an annular shape when viewed from the top.

Suction lines 240a, 240b, and 240c are independently provided in the regions 230a, 230b, and 230c, respectively. Separate vacuum pumps 241a, 241b, and 241c are connected to the suction lines 240a, 240b, and 240c, respectively. The upper chuck 230 is capable of vacuum-attracting the upper wafer W1 in each of the regions 230a, 230b, and 230c individually.

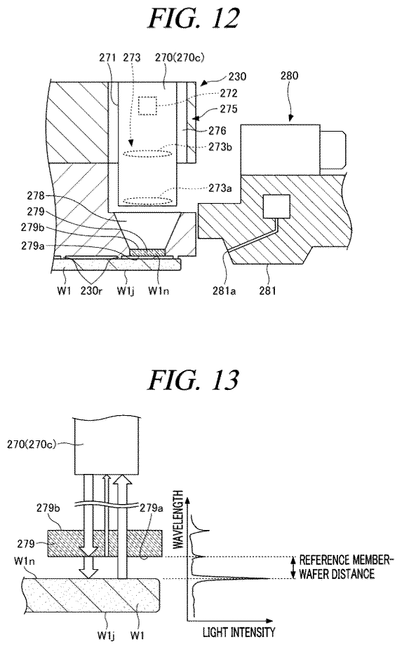

The upper chuck 230 has ribs 230r (see FIG. 12) arranged radially and extending in multiple ring shapes, and protruding ends of these ribs 230r form an attraction surface. The suction lines 240a, 240b, and 240c communicate with a line installation surface between the ribs 230r, and apply an attracting pressure to spaces surrounded by the upper wafer W1, the individual ribs 230r, and the line installation surface to attract the upper wafer W1. The height of each rib 230r from the line installation surface is not particularly limited, but may be set to, e.g., about 0.2 mm.

The upper chuck 230 is provided with a multiple number of holding pins 245 configured to be movable up and down in the vertical direction. The plurality of holding pins 245 are connected to a vacuum pump 246, and the upper wafer W1 is vacuum-attracted to the holding pins 245 by the operation of the vacuum pump 246. The upper wafer W1 is vacuum-attracted to lower ends of the multiple number of holding pins 245. Instead of the multiple number of holding pins 245, a ring-shaped attraction pad may be used.

The multiple number of holding pins 245 are protruded from an attraction surface of the upper chuck 230 as they are lowered by a non-illustrated driver. In this state, the holding pins 245 receive the upper wafer W1 from the transfer device 61 by vacuum-attracting it. Thereafter, the multiple number of holding pins 245 are raised, allowing the upper wafer W1 to come into contact with the attraction surface of the upper chuck 230. Then, the upper chuck 230 vacuum-attracts the upper wafer W1 horizontally in the respective regions 230a, 230b, and 230c by the operations of the vacuum pumps 241a, 241b, and 241c, respectively.

In addition, the upper chuck 230 has a through hole 243 which is formed through a central portion of the upper chuck 230 in the vertical direction. A pushing member 250 is inserted through the through hole 243. The pushing member 250 presses the center of the upper wafer W1 spaced apart from the lower wafer W2, thus bringing the upper wafer W1 into contact with the lower wafer W2.

The pushing member 250 has a pushing pin 251 and an outer cylinder 252 serving as an elevation guide for the pushing pin 251. The pushing pin 251 is inserted through the through hole 243 by, for example, a driver (not shown) having a motor therein, and is protruded from the attraction surface of the upper chuck 230, pressing the center of the upper wafer W1.

Further, the lower chuck 231 is also divided into a plurality of (for example, two) regions 231a and 231b along the radial direction of the lower chuck 231. These regions 231a and 231b are provided in this order from the center of the lower chuck 231 toward the outer periphery thereof. The region 231a is formed in a perfect circle shape when viewed from the top, and the region 231b is formed in an annular shape when viewed from the top. The region 231b may have multiple arc-shaped zones (smaller regions) along the circumferential direction.

Suction lines 260a and 260b are independently provided in the regions 231a and 231b, respectively. Separate vacuum pumps 261a and 261b are connected to the suction lines 260a and 260b, respectively. This configuration allows the lower chuck 231 to vacuum-attract the lower wafer W2 in the regions 231a and 231b individually.

The lower chuck 231 is provided with a plurality of (for example, three) holding pins 265 configured to be movable up and down in the vertical direction. The lower wafer W2 is placed on upper ends of the plurality of holding pins 265. Further, the lower wafer W2 may be vacuum-attracted to the upper ends of the plurality of holding pins 265.

The plurality of holding pins 265 are protruded from the attraction surface of the lower chuck 231 as they are raised. In this state, the plurality of holding pins 265 receive the lower wafer W2 from the transfer device 61. Thereafter, the plurality of holding pins 265 are lowered, thus allowing the lower wafer W2 to come into contact with the attraction surface of the lower chuck 231. Subsequently, the lower chuck 231 vacuum-attracts the lower wafer W2 horizontally in the plurality of regions of the attraction surface.

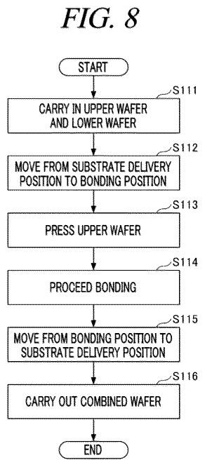

Now, with reference to FIG. 8 to FIG. 10C, the process of producing the bonded wafer T in the process S109 of FIG. 4 will be described in detail. As depicted in FIG. 8, the control device 90 controls the transfer device 61 to carry the upper wafer W1 and the lower wafer W2 into the bonding module 41 (process S111). As for the relative positions of the upper chuck 230 and the lower chuck 231 after being carried in, they are at the substrate delivery position as shown in FIG. 6 and FIG. 7.

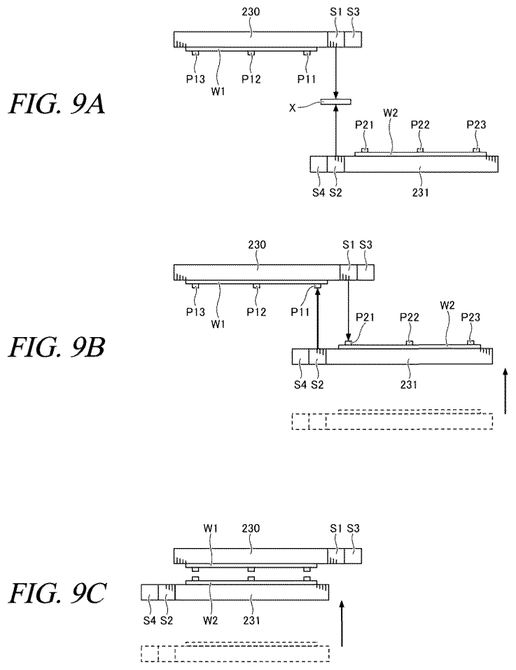

Next, the control device 90 controls the moving mechanism 290 to move the relative positions of the upper chuck 230 and the lower chuck 231 from the substrate delivery position to the bonding position shown in FIG. 7 (process S112). In this process S112, the control device 90 carries out alignment between the upper wafer W1 and the lower wafer W2 by using a first camera S1 and a second camera S2 as shown in FIG. 9A to FIG. 9C.

The first camera S1 is fixed to the upper chuck 230 to image the lower wafer W2 held by the lower chuck 231. Multiple reference points P21 to P23 are previously formed on the bonding surface W2j of the lower wafer W2. As the reference points P21 to P23, patterns of electronic circuits or the like may be used. The number of the reference points is not particularly limited.

Meanwhile, the second camera S2 is fixed to the lower chuck 231 to image the upper wafer W1 held by the upper chuck 230. Multiple reference points P11 to P13 are previously formed on the bonding surface W1j of the upper wafer W1. As the reference points P11 to P13, patterns of electronic circuits or the like may be used. The number of these reference points is not particularly limited.

As depicted in FIG. 9A, the bonding module 41 adjusts the relative positions of first camera S1 and second camera S2 in the horizontal direction by the moving mechanism 290. Specifically, the moving mechanism 290 moves the lower chuck 231 in the horizontal direction such that the second camera S2 is positioned substantially directly below the first camera S1. Then, the first camera S1 and the second camera S2 image a common target X and the moving mechanism 290 finely adjusts the position of the second camera S2 in the horizontal direction such that the positions of the first camera S1 and the second camera S2 in the horizontal direction are coincident.

Subsequently, as shown in FIG. 9B, the moving mechanism 290 moves the lower chuck 231 vertically upwards and adjusts the positions of the upper chuck 230 and the lower chuck 231 in the horizontal direction. Specifically, while the moving mechanism 290 is moving the lower chuck 231 in the horizontal direction, the first camera S1 sequentially images the reference points P21 to P23 of the lower wafer W2, and the second camera S2 sequentially images the reference points P11 to P13 of the upper wafer W1. FIG. 9B shows a state in which the first camera S1 is imaging the reference point P21 of the lower wafer W2 and the second camera S2 is imaging the reference point P11 of the upper wafer W1.

The first camera S1 and the second camera S2 transmit the obtained image data to the control device 90. The control device 90 controls the moving mechanism 290 based on the image data obtained by the first camera S1 and the image data obtained by the second camera S2, and adjusts the position of the lower chuck 231 in the horizontal direction such that the reference points P11 to P13 of the upper wafer W1 and the reference points P21 to P23 of the lower wafer W2 coincide with each other when viewed from the vertical direction.

Thereafter, as illustrated in FIG. 9C, the moving mechanism 290 moves the lower chuck 231 vertically upwards. As a result, a distance G (see FIG. 7) between the bonding surface W2j of the lower wafer W2 and the bonding surface W1j of the upper wafer W1 becomes a predetermined distance of, e.g., 80 μm to 200 μm. The adjustment of the distance G is performed by using a first displacement meter S3 and a second displacement meter S4.

The first displacement meter S3 is fixed to the upper chuck 230, like the first camera S1, and measures the thickness of the lower wafer W2 held by the lower chuck 231. The first displacement meter S3 measures the thickness of the lower wafer W2 by, for example, radiating light to the lower wafer W2 and receiving reflection light reflected from both top and bottom surfaces of the lower wafer W2. For example, this thickness measurement is performed when the moving mechanism 290 moves the lower chuck 231 in the horizontal direction. The first displacement meter S3 carries out the measurement by, for example, a confocal method, a spectral interference method, or a triangulation method. A light source of the first displacement meter S3 is an LED or a laser.

Meanwhile, the second displacement meter S4 is fixed to the lower chuck 231, like the second camera S2, and measures the thickness of the upper wafer W1 held by the upper chuck 230. The second displacement meter S4 measures the thickness of the upper wafer W1 by, for example, radiating light to the upper wafer W1 and receiving reflection light reflected from both top and bottom surfaces of the upper wafer W1. For example, this thickness measurement is performed when the moving mechanism 290 moves the lower chuck 231 in the horizontal direction. The second displacement meter S4 carries out the measurement by, for example, a confocal method, a spectral interference method, or a triangulation method. A light source of the second displacement meter S4 is an LED or a laser.

The first displacement meter S3 and the second displacement meter S4 transmit the obtained data to the control device 90. The control device 90 controls the moving mechanism 290 based on the data obtained by the first displacement meter S3 and the data obtained by the second displacement meter S4, and adjusts the position of the lower chuck 231 in the vertical direction so that the distance G becomes a set value.

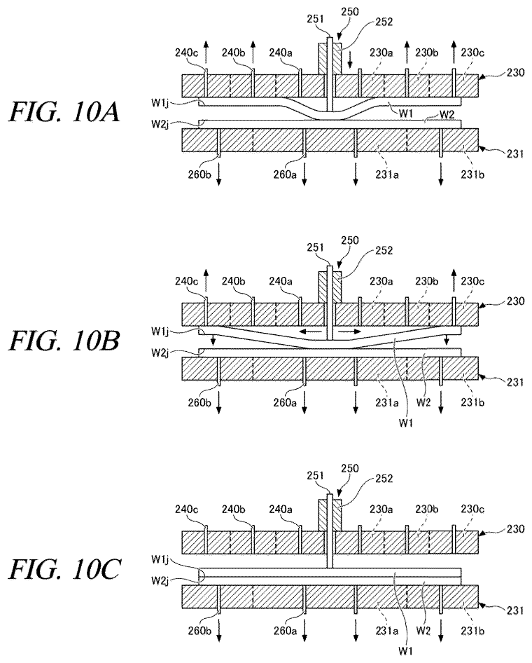

Next, the operation of the vacuum pump 241a is stopped, so that the vacuum attraction of the upper wafer W1 in the region 230a is released, as illustrated in FIG. 10A. Thereafter, the pushing pin 251 of the pushing member 250 is lowered to press the center of the upper wafer W1, allowing the upper wafer W1 to come into contact with the lower wafer W2 (process S113). As a result, the centers of the upper and lower wafers W1 and W2 are bonded to each other.

Since the bonding surface W1j of the upper wafer W1 and the bonding surface W2j of the lower wafer W2 are modified, a van der Waals force (intermolecular force) is first generated between the bonding surfaces W1j and W2j, so that the bonding surfaces W1j and W2j are bonded to each other. Further, since the bonding surface W1j of the upper wafer W1 and the bonding surface W2j of the lower wafer W2 have been hydrophilized, hydrophilic groups (e.g., OH groups) are hydrogen-bonded, allowing the bonding surfaces W1j and W2j to be firmly bonded to each other.

Subsequently, the control device 90 stops the operation of the vacuum pump 241b, and releases the vacuum attraction of the upper wafer W1 in the region 230b, as shown in FIG. 10B. Afterwards, the control device 90 stops the operation of the vacuum pump 241c, and releases the vacuum attraction of the upper wafer W1 in the region 230c, as shown in FIG. 10C.

In this way, the vacuum attraction of the upper wafer W1 is released step by step from the center toward the periphery of the upper wafer W1, so that the upper wafer W1 drops and comes into contact with the lower wafer W2 step by step. Then, the bonding of the upper wafer W1 and the lower wafer W2 proceeds sequentially toward the peripheries of the upper and lower wafers W1 and W2 after the centers thereof are bonded (process S114). As a result, the entire bonding surface W1j of the upper wafer W1 and the entire bonding surface W2j of the lower wafer W2 come into contact with each other, so that the upper wafer W1 and the lower wafer W2 are bonded together, and the bonded wafer T is obtained. Then, the bonding apparatus 1 raises the pushing pin 251 to its original position.

After the bonded wafer T is formed, the control device 90 controls the moving mechanism 290 to move the relative positions of the upper chuck 230 and the lower chuck 231 from the bonding positions shown in FIG. 7 to the substrate delivery positions shown in FIG. 5 and FIG. 6 (process S115). By way of example, the moving mechanism 290 first lowers the lower chuck 231 to widen the distance between the lower chuck 231 and the upper chuck 230 in the vertical direction. Then, the moving mechanism 290 moves the lower chuck 231 sideways so that the lower chuck 231 and the upper chuck 230 are placed sideways apart.

Thereafter, the control device 90 controls the transfer device 61 to carry out the bonded wafer T from the bonding module 41 (process S116). Specifically, the lower chuck 231 first releases the holding of the bonded wafer T. Then, the plurality of holding pins 265 are raised to hand the bonded wafer T over to the transfer device 61. Thereafter, the plurality of holding pins 265 are lowered to their original positions.

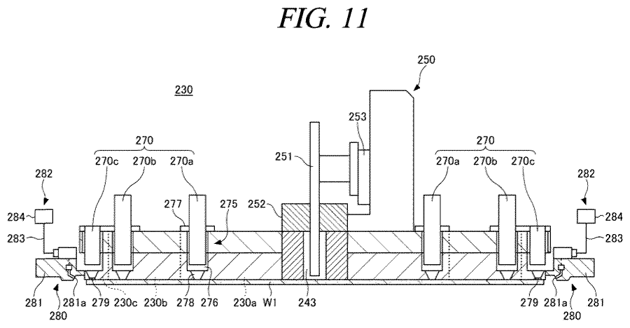

In the above-described bonding apparatus 1, the upper chuck 230 has a plurality of displacement sensors 270 configured to measure the height position of the upper wafer W1 in order to monitor the progress of the bonding between the upper wafer W1 and the lower wafer W2, as shown in FIG. 11. The displacement sensor 270 is an optical sensor configured to radiate measurement light to the upper wafer W1 and receive reflection light from the upper wafer W1 to obtain measurement information. Furthermore, the bonding apparatus 1 is also equipped with a gas supply mechanism 280 around the upper chuck 230, and this gas supply mechanism 280 serves to supply a void reducing gas to the vicinity of the outer peripheries of the upper wafer W1 and the lower wafer W2 during the bonding.

The plurality of displacement sensors 270 are arranged at, for example, three different radius positions from the center of the upper chuck 230 toward the outside in the radial direction, and are arranged at an equal distance along the circumferential direction of the same radius positions. As an example, three displacement sensors 270 with different radius positions are provided in the regions 230a, 230b, and 230c set in the upper chuck 230, respectively. Hereinafter, the displacement sensor 270 located in the region 230a is also referred to as an inner displacement sensor 270a, the displacement sensor 270 located in the region 230b is also referred to as an intermediate displacement sensor 270b, and the displacement sensor 270 located in the region 230c is also referred to as an outer displacement sensor 270c.

The respective displacement sensors 270 (the inner displacement sensors 270a, the intermediate displacement sensors 270b, and the outer displacement sensors 270c) are provided so as to face the upper wafer W1 held by the upper chuck 230. The upper chuck 230 has placement sections 275 for respectively placing therein the displacement sensors 270. Each placement section 275 includes a recess 276 for accommodating therein a part or the whole of the displacement sensor 270, a fixing member 277 configured to fix the displacement sensor 270, and an aperture 278 allowing the recess 276 to communicate with a space on the attraction surface side of the upper chuck 230. The respective fixing members 277 fix the respective displacement sensors 270 such that leading ends (lower ends) of the respective displacement sensors 270 lie on the same height position. The aperture 278 is formed through a bottom of the recess 276 and is tapered toward the attraction surface, thereby reducing the range of the measurement light of the displacement sensor 270.

As shown in FIG. 12, each displacement sensor 270 placed in the placement section 275 is capable of measuring the distance to the front surface (non-bonding surface W1n) of the upper wafer W1 facing thereto through a space ranging from the leading end of the displacement sensor 270 to the upper wafer W1. In other words, the space from the leading end of the displacement sensor 270 to the non-bonding surface Win of the upper wafer W1 forms a measurement light path of the displacement sensor 270. The displacement sensor 270 is connected to the control device 90 so as to be able to communicate with the control device 90, and transmits the acquired information to the control device 90 under a command of the control device 90 or automatically. The control device 90 functions as a processor that processes the information from each displacement sensor 270.

For each displacement sensor 270, a white confocal type sensor, which is configured to emit white (multi-color) measurement light to the upper wafer W1 and measure the distance by using information of the reflection light reflected from the front surface (non-bonding surface W1n) of the upper wafer W1, may be applied, for example. The white confocal type displacement sensor 270 has a housing 271, a white LED 272, and a lens module 273 that focuses the measurement light emitted from the white LED 272 at different positions on the optical axis of the measurement light, for each color (for each of multiple wavelengths) thereof. The lens module 273 may be one in which multiple types of lenses 273a and 273b are arranged in the lengthwise direction of the displacement sensor 270. The white confocal type displacement sensor 270 also has a non-illustrated measuring device configured to disperse the reflection light and measure its spectrum (reflection spectrum).

By way of example, the displacement sensor 270 sets the focal length of blue light to the farthest position, the focal length of red light to the closest position, and the focal length of green light to an intermediate position between them. The light of the color (wavelength) whose focal point coincides with the top surface of the upper wafer W1 is most strongly reflected. Thus, the displacement sensor 270 is capable of measuring the relative distance between the displacement sensor 270 and the upper wafer W1 from a peak wavelength of the reflection spectrum. Here, the order and the distances of the focal positions of the red light, the green light, and the blue light are not particularly limited, and may be set as required according to a device to which the displacement sensor 270 is applied. In this way, by employing the white confocal type displacement sensor 270, the displacement sensor 270 does not need to be brought into contact with the upper wafer W1 during the measurement, and high measurement accuracy can be obtained. However, the displacement sensor 270 is not limited to the confocal type sensor, and any of various types of optical sensors, such as a spectral interference type and a triangulation type, may be used.

As shown in FIG. 11 and FIG. 12, the gas supply mechanism 280 has a gas discharger 281 and a supply 282. The gas discharger 281 is formed in, for example, a circular ring shape that goes around a lateral side of a side peripheral surface of the upper chuck 230. The gas discharger 281 has a plurality of discharge ports 281a evenly arranged along the circumferential direction. The surface of the gas discharger 281 having the discharge ports 281a is formed as an inclined surface that can guide a gas to between the upper wafer W1 and the lower wafer W2. This gas discharger 281 is capable of discharging a gas approximately evenly to between the upper wafer W1 and the lower wafer W2 and in the vicinity of the outer peripheries of the two wafers W1 and W2 along the circumferential direction.

The supply 282 includes a supply path 283 connected to the gas discharger 281, and a gas source 284 provided at an upstream end of the supply path 283. The supply 282 may also be equipped with an opening/closing valve configured to open or close the flow path of the supply path 283, a flow rate controller configured to adjust the flow rate of the gas, and the like (both are not shown) at portions of the supply path 283.

The gas discharged by the gas supply mechanism 280 includes a condensation suppressing gas for suppressing condensation between the upper wafer W1 and the lower wafer W2, a gas having a smaller molecular size than air (a nitrogen (N₂) gas and an oxygen (O₂) gas), and so forth. These gases are intended to reduce an edge void, which is a defect in the bonding interface that occurs between the vicinity of the outer periphery of the upper wafer W1 and the vicinity of the outer periphery of the lower wafer W2, and are hereinafter also referred to as a void reducing gas.

Examples of the void reducing gas include a noble gas such as a helium (He) gas, a neon (Ne) gas or an argon (Ar) gas, a hydrogen (H₂) gas, or a combination of multiple types of these gases. These gases have smaller molecular sizes than the nitrogen gas and the oxygen gas, and have a high Joule-Thomson effect, so they can be said to be gases that are highly effective in suppressing the condensation. Further, the void reducing gas is also a low-humidity gas that does not contain moisture (or have moisture reduced as much as possible).

The supply 282 according to the exemplary embodiment is configured to supply a helium gas as the void reducing gas to the gas discharger 281. Also, the gas supply mechanism 280 may include multiple supply paths 283 and gas sources 284 and be configured to selectively supply multiple types of gases to the gas discharger 281 at different timings. By way of example, the gas supply mechanism 280 may be configured to supply a low-humidity gas at a first timing, such as before the start of the bonding, and to supply a void reducing gas, which is a gas different from the low-humidity gas, at a second timing, such as during the bonding process or the like.

Incidentally, the void reducing gas discharged by the gas supply mechanism 280 may enter the measurement light path of the placement section 275 provided in the upper chuck 230, or the housing 271 of the displacement sensor 270. The void reducing gas that has entered the measurement light path causes a change in the refractive index of the measurement light and the reflection light of the displacement sensor 270. In particular, as shown in FIG. 12, each outer displacement sensor 270c is disposed adjacent to the gas supply mechanism 280 in order to measure the height position of the outer periphery of the upper wafer W1. For this reason, the void reducing gas discharged by the gas discharger 281 of the gas supply mechanism 280 relatively easily enters the measurement light path such as the recess 276 or the aperture 278 of the placement section 275 in which the outer displacement sensor 270c is located.

The refractive index of the light changes due to the void reducing gas, which causes a deviation in measurement values of the outer displacement sensor 270c. As an example, when the helium gas is used as the void reducing gas, the refractive index of the light in the helium gas is 1.000035. Meanwhile, the refractive index of the light in air without the helium gas is 1.000292. The length of the measurement light path from the displacement sensor 270 to the upper wafer W1 is set to, e.g., 10 mm, and a deviation amount between a measurement value when this measurement light path is filled with the air and a measurement value when it is filled with the helium gas is calculated. This deviation amount is 10 mm×(1.000292−1.000035)=0.00257 mm=2.57 μm.

Such deviation in the measurement values becomes a factor that causes a loss of a displacement of the upper wafer W1 when the upper wafer W1 is separated from the upper chuck 230 during the bonding of the upper wafer W1 and the lower wafer W2. In particular, the variation in the measurement value of the displacement sensor 270 is affected by an introduction amount and an introduction timing of the void reducing gas. In this regard, in the control device 90, it is difficult to determine whether the upper wafer W1 has been actually displaced or the void reducing gas has been introduced without the upper wafer W1 being displacement, simply by monitoring the measurement value.

As a resolution, in the bonding apparatus 1 according to the exemplary embodiment, a transparent member 279, which serves as a reference member when measuring the height position of the upper wafer W1, is provided in the placement section 275. In the optical measurement by the displacement sensor 270, the bonding apparatus 1 acquires a reference member-wafer distance between the transparent member 279 and the upper wafer W1, and monitors a variation in the height position of the upper wafer W1 based on this reference member-wafer distance.

To elaborate, the transparent member 279 is formed to be thinner than the aperture 278, and is placed at a lower end position of the aperture 278 where an opening area is the smallest. This lower end opening of the aperture 278 is connected to the line installation surface from which each rib 230r is protruded. For example, the transparent member 279 is fitted to an inner peripheral surface of the lower end of the aperture 278 to be fixed strongly (i.e., undisplaceably or not able to be displaced or moved) to the upper chuck 230 so as to be connected to the line installation surface on a level with it.

The transparent member 279 is light-transmissive, and has a reference surface 279a facing the upper wafer W1 and an opposite surface 279b facing the displacement sensor 270. In a holding state in which the upper wafer W1 is attracted and held before being bonded, the distance between the reference surface 279a of the transparent member 279 and the non-bonding surface W1n of the upper wafer W1, i.e., the reference member-wafer distance, may be desirably set to be in the range of about 0 mm to 5 mm. In the exemplary embodiment, as the upper chuck 230 attracts the upper wafer W1 with the multiple ribs 230r therebetween, the reference member-wafer distance in the holding state is set to be about 0.25 mm.

The transparent member 279 may be made of a resin material having transparency, or an inorganic material such as quartz or ceramic. The light transmittance of the transparent member 279 is desirably 100%, but may be lower than 100%.

As shown in FIG. 13, the displacement sensor 270 and the placement section 275 can obtain a reflection spectrum of the light having passed through the transparent member 279 and then reflected off the non-bonding surface W1n of the upper wafer W1 as well as a reflection spectrum of the light reflected off the reference surface 279a of the transparent member 279 in response to the radiation of the measurement light. A deviation between the peak wavelengths of the light intensities of the respective reflection spectrums corresponds to a difference between the positions of the transparent member 279 and the upper wafer W1. Therefore, the displacement sensor 270 can calculate the reference member-wafer distance between the reference surface 279a and the non-bonding surface W1n based on the reflection spectrums (light intensities and wavelengths), which is the measurement information.

The bonding apparatus 1 may be configured to calculate the reference member-wafer distance from the measured reflection spectrums in a control board provided in the displacement sensor 270, and transmit the measurement information to the control device 90. Alternatively, the bonding apparatus 1 may obtain the measurement information of the reflection spectrums by the displacement sensor 270, transmit the measurement information to the control device 90, and calculate the reference member-wafer distance in the control device 90. In either case, the control device 90 is capable of acquiring the reference member-wafer distance.

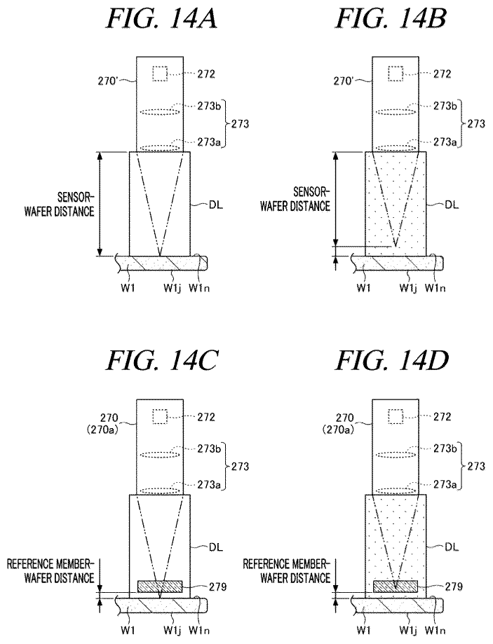

As described above, the displacement sensor 270, the placement section 275 including the transparent member 279, and the control device 90 constitute a measuring device configured to measure the position of the upper wafer W1, which is a substrate. The measuring device can accurately detect the position of the substrate by using the reference member-wafer distance in the measurement by the displacement sensor 270. Below, the significance of the measuring device's monitoring the height position of the upper wafer W1 using the reference member-wafer distance will be explained with reference to FIG. 14A to FIG. 14D.

As in a reference example shown in FIG. 14A, a measuring device configured to measure a sensor-wafer distance in measurement by a displacement sensor 270′ monitors the total distance of a measurement light path DL ranging from the displacement sensor 270′ to the upper wafer W1. In this case, when the helium gas (void reducing gas) is introduced into the measurement light path DL as shown in FIG. 14B, the refractive index of the entire measurement light path DL changes.

As the refractive index of the entire measurement light path DL changes in this way, the measuring device is significantly affected by the refractive index for the sensor-wafer distance to be calculated. For example, as shown in FIG. 14B, the void reducing gas causes an error that the measurement value of the sensor-wafer distance is decreased or increased (meaning that the sensor-wafer distance is shortened or lengthened). Therefore, in the measuring device according to the reference example, it is difficult to distinguish between a change in the measurement value due to the displacement of the upper wafer W1 and a change in the measurement value due to the introduction of the void reducing gas.

In this regard, the measuring device according to the exemplary embodiment shown in FIG. 14C calculates the reference member-wafer distance, which is the distance between the upper wafer W1 and the transparent member 279, in the measurement by the displacement sensor 270. In this case as well, when the helium gas is introduced between the displacement sensor 270 and the transparent member 279 and between the transparent member 279 and the upper wafer W1 in the measurement light path DL, the respective refractive indices of the measurement light path DL change, as shown in FIG. 14D.

However, in the exemplary embodiment, as the refractive index of the measurement light path DL between the displacement sensor 270 and the transparent member 279 changes, both the position of the transparent member 279 and the position of the upper wafer W1 measured by the displacement sensor 270 change. In other words, even if the refractive index of the measurement light path DL between the displacement sensor 270 and the transparent member 279 changes, the relative positions of the transparent member 279 and the upper wafer W1 measured by the displacement sensor 270 will not change.

In addition, the change in the refractive index between the transparent member 279 and the upper wafer W1 due to the introduction of the void reducing gas causes a deviation in the relative position between the transparent member 279 and the upper wafer W1. However, as stated above, the reference member-wafer distance in the holding state is about 0.25 mm, which is only a small percentage of the total length of the measurement light path DL. For example, when the total length of the measurement light path DL is set to 10 mm, the percentage is only 0.25%. In other words, even if the refractive index between the transparent member 279 and the upper wafer W1 changes, the deviation in the relative position between the transparent member 279 and the upper wafer W1 is only very small. Therefore, if the control device 90 monitors the reference member-wafer distance, it becomes possible to easily distinguish between the change in the measurement value due to the displacement of the upper wafer W1 and the change in the measurement value due to the introduction of the void reducing gas.

From the above, when providing the transparent member 279 in the measurement light path DL, it is desirable to provide the transparent member 279 so that the ratio of the reference member-wafer distance to the total length of the measurement light path DL is as small as possible. By way of example, it is desirable to set the ratio of the reference member-wafer distance to the total length of the measurement light path DL to 5% or less (0% to 5%), and more desirably to 1% or less.

Further, as illustrated in FIG. 11, in the bonding apparatus 1, the transparent member 279 is installed in the measurement light path DL of only the outer displacement sensor 270c which is close to the gas supply mechanism 280. In other words, in the bonding apparatus 1, the transparent member 279 is not installed in the inner displacement sensor 270a and the intermediate displacement sensor 270b, which are the displacement sensors 270 located at the inner side than the outer displacement sensor 270c in the radial direction. This is because the amount of introduction of the void reducing gas supplied to the vicinity of the outer peripheries of the upper wafer W1 and the lower wafer W2 into the measurement light path DL of each of the respective inner displacement sensors 270a and intermediate displacement sensors 270b is small. As a consequence, the manufacturing cost and the number of manufacturing processes involved for the manufacture of the bonding apparatus 1 can be reduced. Therefore, for each of the inner displacement sensors 270a and intermediate displacement sensors 270b, the control device 90 calculates the sensor-wafer distance. In this way, by simply changing the calculation method (reference member-wafer distance vs. sensor-wafer distance) depending on the presence or absence of the transparent member 279, the control device 90 can monitor the height position of the upper wafer W1 in the same way. However, the bonding apparatus 1 may also be configured to acquire the reference member-wafer distance for each of the inner displacement sensors 270a and intermediate displacement sensors 270b by providing the transparent member 279 in each of them as well.

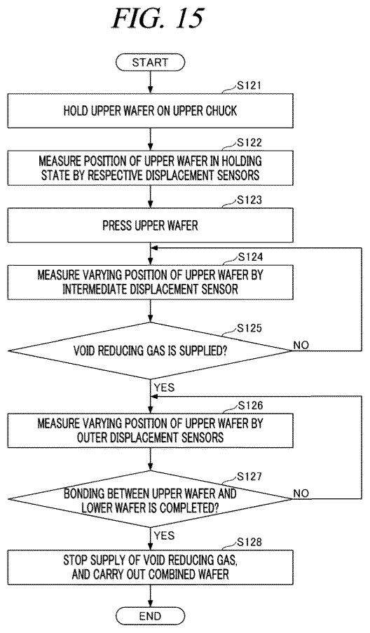

The bonding apparatus 1 according to the exemplary embodiment is basically configured as described above, and a bonding process of the upper wafer W1 and the lower wafer W2, including a measuring method, will be explained below with reference to FIG. 15. In bonding the upper wafer W1 and the lower wafer W2, the control device 90 sequentially performs a process flow of processes S121 to S127 in FIG. 15, for example.

The control device 90 performs a process of attracting and holding the upper wafer W1 by the upper chuck 230 (process S121). The process S121 corresponds to a part of the process S111 in FIG. 8.

Thereafter, the control device 90 measures the height position of the upper wafer W1 in the holding state by each displacement sensor 270 (process S122). At this time, since the gas supply mechanism 280 is not supplying the void reducing gas, air exists in the measurement light path DL of each displacement sensor 270. Through the air, each displacement sensor 270 can accurately measure the height position of the upper wafer W1 in the holding state. Also, the gas supply mechanism 280 may supply a low-humidity gas between the upper wafer W1 and the lower wafer W2 before the upper wafer W1 is pressed down, thereby facilitating low humidity.

For example, in the measurement by the displacement sensor 270, the process of radiating the measurement light to the upper wafer W1 and receiving the reflection light from the upper wafer W1 and the reflection light from the transparent member 279 is performed as described above. Then, the control device 90 performs a process of acquiring the reference member-wafer distance between the upper wafer W1 and the transparent member 279 based on the measurement information of the displacement sensor 270 to recognize the height position of the upper wafer W1.

Next, the pushing member 250 of the bonding apparatus 1 lowers the pushing pin 251 to push down the center of the upper wafer W1 (process S123). As a result, the bonding of the upper wafer W1 and the lower wafer W2 is started. This process S123 corresponds to the process S113 in FIG. 8.

Once the bonding is started, the control device 90 measures the varying height position of the upper wafer W1 by using the respective displacement sensors 270 (process S124). As stated above, the bonding of the upper wafer W1 and the lower wafer W2 progresses outwards in the radial direction from their centers. Therefore, the control device 90 can monitor the progress of the bonding of the upper wafer W1 and the lower wafer W2 by mainly using the measurement values of the intermediate displacement sensors 270b.

The control device 90 determines the timing for supplying the void reducing gas from the gas supply mechanism 280 during the bonding process of the upper wafer W1 and the lower wafer W2 (process S125). By way of example, the control device 90 monitors the measurement value of each intermediate displacement sensor 270b, and makes a determination to supply the void reducing gas from the gas supply mechanism 280 at the time when the descent of the upper wafer W1 is detected in each intermediate displacement sensor 270b. If the descent of the upper wafer W1 has not reached the intermediate displacement sensor 270b (process S125: NO), the processing returns to the process S123, and the same process flow as described above is repeated. If, on the other hand, the descent of the upper wafer W1 reaches the intermediate displacement sensor 270b (process S125: YES), the void reducing gas is supplied from the gas supply mechanism 280. As a result, in the bonding apparatus 1, formation of voids in the outer peripheries of the upper wafer W1 and the lower wafer W2 can be suppressed.

Even during the supply of the void reducing gas, the control device 90 measures the varying height position of the upper wafer W1 by the displacement sensors 270 (process S126). In particular, by the time when the void reducing gas is supplied, the bonding between the upper wafer W1 and the lower wafer W2 has reached their outer peripheries, so the control device 90 monitors the measurement values of the outer displacement sensors 270c to recognize the progress of the bonding between the upper wafer W1 and the lower wafer W2.

As shown in FIG. 14D, each outer displacement sensor 270c measures the height position of the upper wafer W1 through the transparent member 279, in other words, the reference member-wafer distance. Therefore, even if the refractive index of the measurement light path DL changes due to the void reducing gas, the control device 90 can stably obtain the reference member-wafer distance while suppressing a deviation caused by the change in the refractive index.

Therefore, the control device 90 makes a determination upon whether the bonding of the upper wafer W1 and the lower wafer W2 is completed, based on the measurement information of each outer displacement sensor 270c (process S127). If the bonding of the upper wafer W1 and the lower wafer W2 is being carried on (process S127: NO), the processing returns to the process S125, and the same process flow as stated above is repeated. On the other hand, if the bonding of the upper wafer W1 and the lower wafer W2 is completed (process S127: YES), the processing proceeds to a process S128.

In the process S128, the control device 90 controls the gas supply mechanism 280 to stop the supply of the void reducing gas, and also controls a carrying-out process of carrying out the formed bonded wafer T. The carrying-out process of the bonded wafer T corresponds to the processes S115 and S116 in FIG. 8.

As described above, the bonding apparatus 1 and the measuring device according to the exemplary embodiment is equipped with the transparent member 279 between the upper wafer W1 and the displacement sensor 270, and acquires the reference member-wafer distance between the upper wafer W1 and the transparent member 279. This allows the control device 90 to appropriately recognize the position of the upper wafer W1 based on its relative position with respect to the transparent member 279. Furthermore, the displacement sensor 270 or the control device 90 can easily and accurately acquire the distance between the upper wafer W1 and the transparent member 279 by using the measurement information of the reflection spectrum.

In particular, when the measuring device is applied to the bonding apparatus 1, it becomes possible to properly monitor the progress of the bonding of the upper wafer W1 and the lower wafer W2. That is, the control device 90 can properly recognize the displacement of the upper wafer W1 with respect to the upper chuck 230 by obtaining the reference member-wafer distance of the upper wafer W1 held on the upper chuck 230 and the reference member-wafer distance of the upper wafer W1 separated from the upper chuck 230. In this way, the bonding apparatus 1 and the measuring device can accurately recognize the varying position of the substrate by using the reference member-wafer distance between the upper wafer W1 and the transparent member 279, even when the state (refractive index) of the gas in the measurement light path DL does not change.

In addition, even when the void reducing gas is introduced into the measurement light path DL as a result of supplying the void reducing gas from the gas supply mechanism 280, the bonding apparatus 1 can suppress a deviation in the measurement value through the use of the reference member-wafer distance, thus capable of stably measuring the height position of the upper wafer W1. Moreover, in the bonding apparatus 1, by installing the transparent member 279 in the outer displacement sensor 270c to obtain the reference member-wafer distance while not installing the transparent member 279 in the inner displacement sensor 270a and the intermediate displacement sensor 270b, it becomes possible to reduce the manufacturing cost and the number of manufacturing processes.

Besides, by calculating the distance between the reference surface 279a of the transparent member 279 and the non-bonding surface Win of the upper wafer W1 as the reference member-wafer distance, the bonding apparatus 1 can reduce the distance between the upper wafer W1 and the transparent member 279 as much as possible, thereby reducing a measurement deviation. For example, by setting the ratio of the reference member-wafer distance with respect to the total length of the measurement light path DL to 5% or less, a positional deviation in the measurement result can be sufficiently suppressed even if a gas is introduced between the upper wafer W1 and the transparent member 279, resulting in a change in the refractive index. Furthermore, in the bonding apparatus 1, by installing the transparent member 279 in the aperture 278, the transparent member 279 can be easily and firmly fixed.

The bonding apparatus 1, the measuring device, and the measuring method of the present disclosure are not limited to the exemplary embodiment described above, and may adopt various modification examples. For example, the bonding apparatus 1 is not limited to the configuration in which the displacement sensor 270, which is an optical sensor, is installed only in the upper chuck 230, and the displacement sensor 270 (and the transparent member 279) may be installed in the lower chuck 231 as well.

As another example, the displacement sensor 270 or the control device 90 is not limited to acquiring the distance between the reference surface 279a of the transparent member 279 and the non-bonding surface Win of the upper wafer W1, but may acquire a distance between the opposite surface 279b of the transparent member 279 and the non-bonding surface W1n of the upper wafer W1. In this case as well, the displacement sensor 270 or the control device 90 can accurately acquire the position of the transparent member 279 based on reflection light reflected off the opposite surface 279b.

The substrate processing apparatus to which the optical sensor (displacement sensor 270) and the transparent member 279 are applied is not limited to the bonding apparatus 1, but may be any of various types of apparatuses using the optical sensor to measure the position of a substrate. By way of example, the optical sensor and the transparent member 279 may be applied to a separating apparatus, which is a substrate processing apparatus configured to separate the upper wafer W1 and the lower wafer W2 from the bonded wafer T, and the same processing as described above may be performed. As still another example, even in a substrate processing apparatus configured to perform a substrate processing by supplying a gas into a processing vessel in which a substrate is accommodated, the above-described optical sensor and the transparent member 279 may be applied to measure the position of the substrate, and the same processing as described above may be performed. As yet another example, the transparent member 279 may be applied even to a measuring device in which an optical sensor is mounted to an end effector of a transfer device and the position of a substrate is measured by the end effector being moved, and the same processing as described above may be performed.

It should be noted that the substrate processing apparatus, the measuring device, and the measuring method according to the exemplary embodiments are illustrative in all respects and are not anyway limiting. The above-described exemplary embodiments can be modified and improved in various ways without departing from the scope and the spirit of claims. Unless contradictory, other configurations may be adopted, and the disclosures in the various exemplary embodiments can be combined appropriately.

According to the exemplary embodiment, it is possible to measure the position of the substrate accurately.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a holder configured to hold a substrate allowed to be separated;
an optical sensor provided in the holder, the optical sensor being configured to radiate measurement light to the substrate and receive reflection light from the substrate;
a transparent member placed in a measurement light path between the substrate and the optical sensor, the transparent member being light-transmissive; and
a controller having a processor and a memory with a computer readable program stored therein that upon execution of the computer readable program by the processor configures the controller to:
process measurement information from the optical sensor, and
acquire a distance between the substrate and the transparent member based on the measurement information to recognize a position of the substrate.

2. The substrate processing apparatus of claim 1,
wherein the optical sensor or the controller acquires the distance between the substrate and the transparent member based on a spectrum of the reflection light included in the measurement information.

3. The substrate processing apparatus of claim 2,
wherein the distance acquired by the controller includes a first distance between the substrate held by the holder and the transparent member, and a second distance between the substrate separated from the holder and the transparent member.

4. The substrate processing apparatus of claim 3,
wherein the substrate includes a first substrate and a second substrate,
the holder includes:
a first holder configured to hold the first substrate; and
a second holder configured to hold the second substrate at a position facing the first substrate,
the substrate processing apparatus is a bonding apparatus that pushes out the first substrate from the first holder and bonds the first substrate and the second substrate with each other, and
the controller is configured to recognize progress of bonding of the first substrate and the second substrate based on the measurement information of the optical sensor provided in the first holder.

5. The substrate processing apparatus of claim 4, further comprising:
a gas supply mechanism configured to supply a void reducing gas to between outer peripheries of the first substrate and the second substrate before being bonded to each other,
wherein the optical sensor acquires the distance between the substrate and the transparent member in each of a state that the void reducing gas is not present in the measurement light path and a state that the void reducing gas is present in the measurement light path.

6. The substrate processing apparatus of claim 5,
wherein the gas supply mechanism is provided radially outside of the first holder,
the optical sensor includes multiple optical sensors,
the first holder comprises the multiple optical sensors along a radial direction of the substrate held by the first holder, and
the transparent member is provided in one of the multiple optical sensors located at an outermost position in the radial direction.

7. The substrate processing apparatus of claim 6,
wherein the controller is configured to acquire the distance between the substrate and the transparent member based on the measurement information of the one optical sensor located at the outermost position, while obtaining the distance between the substrate and the optical sensor based on the measurement information of another one of the multiple optical sensors located at an innermost position in the radial direction.

8. The substrate processing apparatus of claim 1,
wherein the optical sensor or the controller is configured to calculate a distance between a surface of the substrate facing the transparent member and a surface of the transparent member facing the substrate.

9. The substrate processing apparatus of claim 1,
wherein the holder comprises a placement section in which the optical sensor is placed therein, and
the placement section has an aperture configured to reduce a range of the measurement light in the measurement light path, and the transparent member is fixed to the aperture.

10. The substrate processing apparatus of claim 1,
wherein a ratio of the distance between the substrate and the transparent member to a total length of the measurement light path is 5% or less.

11. The substrate processing apparatus of claim 1,
wherein the optical sensor is a confocal type displacement sensor.

12. A measuring device, comprising:
an optical sensor configured to:
radiate measurement light to a substrate, the substrate being displaceable relative to the measuring device, and
receive reflection light from the substrate;
a transparent member placed between the substrate and the optical sensor, the transparent member being light-transmissive; and
a controller having a processor and a memory with a computer readable program stored therein that upon execution of the computer readable program by the processor configures the controller to:
process measurement information from the optical sensor, and
acquire a distance between the substrate and the transparent member based on the measurement information to recognize the position of the substrate.

13. The substrate processing apparatus of claim 12,
wherein the controller is configured to acquire the distance between the substrate and the transparent member based on a spectrum of the reflection light included in the measurement information.

14. The substrate processing apparatus of claim 13,
wherein the distance acquired by the controller includes a first distance between the substrate held by a holder and the transparent member, and a second distance between the substrate separated from the holder and the transparent member.

15. The substrate processing apparatus of claim 14,
wherein the substrate includes a first substrate and a second substrate,
the holder includes:
a first holder configured to hold the first substrate; and
a second holder configured to hold the second substrate at a position facing the first substrate, and
the controller is configured to recognize a progress of bonding of the first substrate and the second substrate based on the measurement information of the optical sensor provided in the first holder.

16. The substrate processing apparatus of claim 15, wherein the optical sensor acquires the distance between the substrate and the transparent member in each of a state that a void reducing gas, supplied by a gas supply mechanism, is not present in a measurement light path and a state that the void reducing gas is present in the measurement light path.

17. A measuring method, comprising:
holding a substrate, allowed to be separated, by a holder;
radiating, by an optical sensor provided in the holder, measurement light to the substrate, and receiving reflection light from the substrate and reflection light from a transparent member, the transparent member is placed in a measurement light path between the substrate and the optical sensor and is light-transmissive; and
acquiring, in a controller, a distance between the substrate and the transparent member based on measurement information from the optical sensor to recognize the position of the substrate.

18. The measuring method of claim 17,
wherein the controller acquires the distance between the substrate and the transparent member based on a spectrum of the reflection light included in the measurement information, and
the distance acquired by the controller includes a first distance between the substrate held by the holder and the transparent member, and a second distance between the substrate separated from the holder and the transparent member.

19. The measuring method of claim 18,
wherein the substrate includes a first substrate and a second substrate,
the holder includes:
a first holder configured to hold the first substrate; and
a second holder configured to hold the second substrate at a position facing the first substrate, and
the method further comprises:
pushing out the first substrate from the first holder and bonding the first substrate and the second substrate with each other; and
recognizing, by the controller, a progress of bonding of the first substrate and the second substrate based on the measurement information of the optical sensor provided in the first holder.

20. The measuring method of claim 19,
wherein the gas supply mechanism is provided radially outside of the first holder,
the optical sensor includes multiple optical sensors,
the first holder comprises the multiple optical sensors along a radial direction of the substrate held by the first holder, and
the transparent member is provided in one of the multiple optical sensors located at an outermost position in the radial direction.
